(19) United States
(12) Patent Application Publication
(10) Pub. No.: US 2009/0261214 A1
(43) Pub. Date: Oct. 22, 2009

(54) Securing And Managing Electronic Cables In A Modular, Rack-Mounted Computer System

(75) Inventors: William Norris Beauchamp, Raleigh, NC (US); David Frederick Champion, Durham, NC (US); Karl Klaus Dittus, Durham, NC (US); Aubrey Lamond Hodges, Creedmoor, NC (US); John Joseph Struble, JR., Mebane, NC (US); Brian Alan Trumbo, Apex, NC (US)

Correspondence Address: IBM CORPORATION (SS/NC);c/o STREETS & STEELE, 13831 NORTHWEST FREEWAY, SUITE 355, HOUSTON, TX, 77040, US

(73) Assignee: INTERNATIONAL BUSINESS MACHINES CORPORATION, Armonk, NY (US)

(21) Appl. No.: 12/106,422

(22) Filed: Apr. 21, 2008

(51) Int. Cl. F16L 3/12; H05K 5/00; A47F 7/00

(52) U.S. Cl. 248/74.1; 312/223.2; 361/724; 211/26

(57) ABSTRACT

A cable clamp has a first clamp member secured to the chassis or to the rack adjacent to one of the module bays and a second clamp member movably secured to the first clamp member. The first clamp member defines a first clamp surface and the second clamp member defines a second clamp surface facing the first clamp surface. An elastic material is secured to a surface of one or both of the first and second clamp surfaces. The second clamp member is movable away from the first clamp member for receiving the one or more electronic cables between the first and second clamp surfaces. A biasing member biases the second clamp member toward the first clamp member sufficient to compress and frictionally engage the elastic material with the one or more electronic cables.

### BACKGROUND OF THE INVENTION

1. Field of the Invention

The present invention relates to connections between components of rack-mounted computer systems, and more particularly to solutions for managing cables in rack-mounted computer systems.

2. Description of the Related Art

A data center is a facility designed for housing one or more modular, rack-mounted computer system and associated equipment. Each rack accommodates computer equipment, primarily in the form of modular computer components, and positions the computer equipment in an organized, closely-packed arrangement that makes efficient use of space and places these components within easy reach of datacenter personnel. The computer equipment in a rack system will typically utilize several different connection types of connectors for interconnecting with various other components, such as internal midplanes or backplanes, and Ethernet switches for making network connections. Cables provide a convenient and versatile way for personnel to connect components located in different positions in a rack. Cables are typically routed externally to the rack for access by personnel. Computer suppliers may at least partially assemble a rack system along with the necessary cabling and ship the pre-cabled rack system to the customer. Datacenter personnel in charge of administering the rack system may route and periodically re-route cables as modular components are changed and moved in the process of using and maintaining the rack system.

Because cabling is prevalent in rack-mounted computer systems, cable management is an important consideration in the design, installation, and management of the rack. Numerous cable connections may be required in a rack, particularly due to the large number of components that may be mounted in a rack and the number of connections that each component may require. Therefore, the ease and efficiency of setting up and maintaining a rack system depends, in part, on how the cables are managed, including how well the cables are arranged and secured on the rack. A well-organized cabling system makes it easier and faster to route the cables between components. Furthermore, the manner in which externally-routed cables are organized also affects the appearance a rack.

### SUMMARY OF THE INVENTION

A first embodiment provides a cable clamp. The cable clamp includes first and second clamp members. The first clamp member is securable to an electronic component chassis next to an electronic module bay and defines a first clamp surface. The second clamp member is movably secured to the first clamp member and defines a second clamp surface facing the first clamp surface. The second clamp member is movable with respect to the first clamp member to change the spacing between the second clamp surface and the first clamp surface. An engagement member is secured to one or both of the first and second clamp surface. A biasing member biases the second clamp member toward the first clamp member to move the second clamp surface toward the first clamp surface.

A second embodiment provides an apparatus, including a computer component chassis configured for removably mounting on a computer equipment rack. The computer component chassis has at least one module bay configured for removably receiving an electronic module. The electronic module has one or more electrical connectors each configured for releasably connecting with an end of a respective one or more electronic cables. A clamp has a first clamp member secured to the chassis or to the rack adjacent to one of the module bays. The first clamp member defines a first clamp surface. A second clamp member defines a second clamp surface facing the first clamp surface, and is movably secured to the first clamp member. The second clamp member is movable away from the first clamp member for receiving the one or more electronic cables between the first and second clamp surfaces. An elastic material is secured to a surface of one or both of the first and second clamp surfaces. A biasing member is provided for biasing the second clamp member toward the first clamp member sufficiently to compress and frictionally engage the elastic material with the one or more electronic cables.

A third embodiment provides a modular computer system including a plurality of electronic modules. Each electronic module has one or more external electrical connectors. One or more chassis each have at least one module bay configured for removably receiving one of the electronic modules. A rack has one or more chassis bays, each chassis bay being configured to receive one of the chassis. Each of a plurality of cables are configured for releasably connecting to the electrical connector of one of the electronic modules. A plurality of cable clamps is also provided. Each cable clamp has a first clamp member secured to the chassis adjacent to one of the module bays and defining a first clamp surface, and a second clamp member defining a second clamp surface opposing the first clamp surface. The second clamp member is movably secured to the first clamp member and movable away from the first clamp member to create a gap for receiving one or more of the electronic cables between the first and second clamp surfaces. An elastic material is secured to a surface of one or both of the first and second clamp surfaces. A biasing member is provided for biasing the second clamp member toward the first clamp member such that the elastic material is compressed against and frictionally engaged with the one or more electronic cables between the first and second clamp surfaces.

A fourth embodiment provides a method. One or more chassis are positioned on a rack, each chassis having at least one module bay configured for removably receiving one of the electronic modules and a clamp having a first clamp member defining a first clamp surface and a second clamp member defining a second clamp surface. An electronic module is positioned in each module bay. Each electronic module has one or more external electrical connectors. The second clamp member is moved away from the first clamp member. One or more of the electronic cables is positioned between the first and second clamp surfaces. The second clamp member is biased toward the first clamp member to frictionally engage the one or more electronic cables between the first and second clamp members. The electronic cables are connected to the electrical connectors on the electronic modules.

Other details and embodiments of the invention will be apparent from the following description and the appended claims.

### BRIEF DESCRIPTION OF THE DRAWINGS

FIG. 1 provides a schematic partial assembly view of a rack for accommodating a number of component chassis.

FIG. 2 is a perspective view of a modular computer component chassis having a cable clamp according to one embodiment of the invention.

FIG. 3 is a front view of the clamp illustrating an exemplary attachment of the clamp to the chassis.

FIG. 4 is a perspective view of the clamp as viewed from the rear, left side.

FIG. 5 is a perspective view of the clamp with the pull plate moved away from the base.

FIG. 6 is another perspective view of the clamp as viewed from the front, right side, showing the pull plate pulled away from and rotated clockwise with respect to the base plate.

FIG. 7 is a side elevation view of the clamp with the cables clamped between the elastic strip on the base plate and elastic strip on the pull plate.

FIG. 8 is a side view of the clamp with an alternative engagement member having ribs projecting from the first and second clamp surfaces.

FIG. 9 is a rear view of a rack on which an exemplary cable management system has been implemented according to another embodiment of the invention

### DETAILED DESCRIPTION OF SELECTED EMBODIMENTS

Embodiments of the invention are directed to various aspects of cabling and cable management in an electronic system, such as in a modular rack system. One embodiment is directed to hardware, including a clamp for quickly and easily securing cables. One or more clamps may be used to hold the cables in the vicinity of each location that the cables are needed. A related embodiment pertains to a method of using such hardware. The cables may remain securely in place when using and maintaining the system, and even during shipment of a pre-cabled system. Another embodiment is directed to a modular computer system including a cable management system for organizing and routing cables to the many different locations they are needed within the rack system. The modular computer system may include multiple instantiations of the hardware selectively distributed throughout the rack for securing cables at each of the various locations that cables are needed. The various embodiments of the invention promote a logical, well-organized layout and a sturdy, reliable support mechanism for the myriad of cables used in a modern rack-based computer system. Accordingly, the efficiency of assembling and maintaining a modular rack-mounted computer system is enhanced.

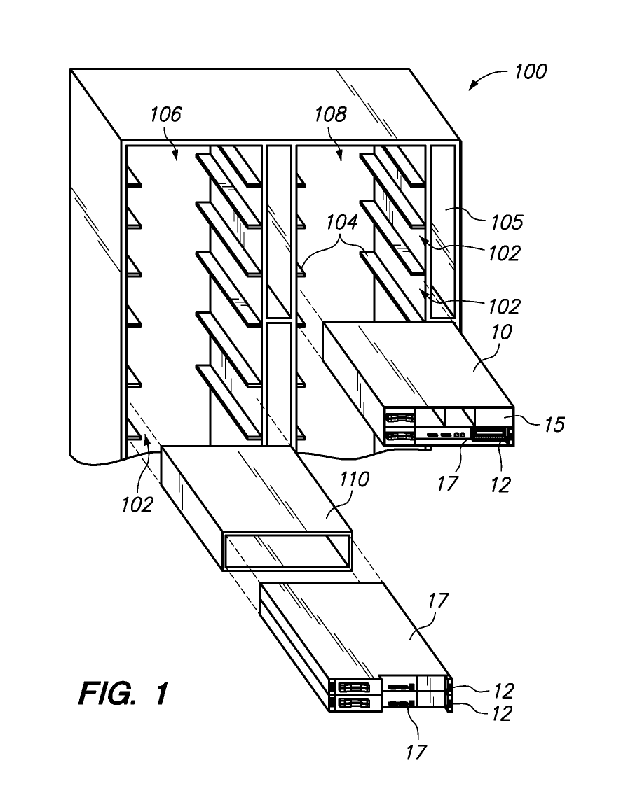

The invention may be applied to a variety of electronic systems in which cables are used to connect components. Due to the abundance of cables in rack-based systems, and the above-stated concerns with regard to cabling a rack system, the exemplary embodiments presented herein are discussed largely in the context of a rack system. FIG. 1 provides a schematic partial assembly view of a rack 100 including a plurality of separate chassis bays 102 arranged in two vertical columns 106, 108. Each chassis bay 102 accommodates one chassis. For example, one exemplary 2U (two-unit) chassis 10 is shown as it would be inserted into one of the chassis bays 102 in the right column 108, and another exemplary chassis 110 is shown as it would be inserted into one of the chassis bays 102 in the left column 106. The exemplary chassis 10, 110 may each be received and supported on respective pairs of horizontal rails 104. Other rails 104 may be given different vertical spacings to accommodate various sizes of chassis. The vertical spacing between rails 104 may be individually adjustable. In the exemplary rack shown, a plurality of network switch bays 105 are provided to the right of each column 106, 108, and are suitable to receive a plurality of network switches (not shown).

Each chassis may accommodate one or more electronic modules depending on the size of the chassis and the number of bays in the chassis. For example, the 2U chassis 10 is shown having received an expansion module 15, including a number of hard drives, and a lower compute module 17. The 2U chassis 110 is shown as it may receive two compute modules 17. Other examples of electronic modules include computer hardware modules such as hard drive modules, PCI card modules, network switches, or other modular computer hardware assemblies. Cable connections may be made at the front of the rack 100 with connectors on the front of the compute modules 10 to other components on the rack 100. For example, various connectors provided on the front of the compute modules 17 may be connected by cables to connectors on components mounted in other bays 102 or to a network switch provided in the network switch bays 105. The cables connected to each compute module 17 may be clamped using a clamp 12 provided next to the compute module 17.

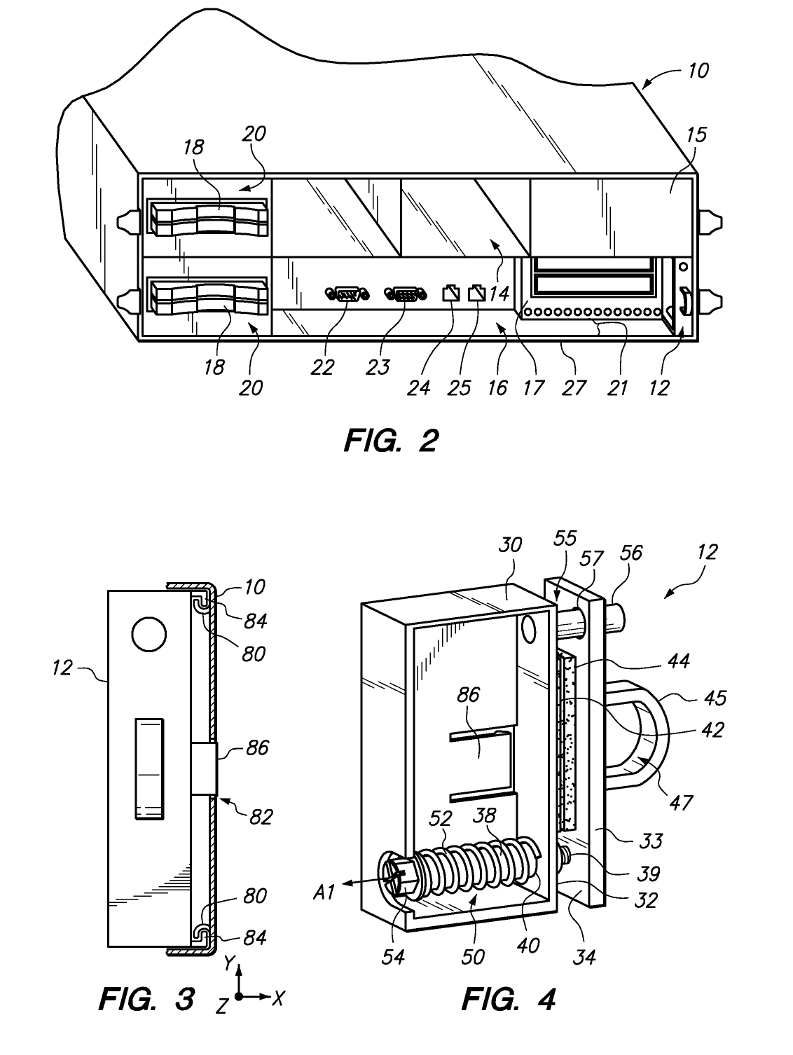

FIG. 2 is a more detailed perspective view of the exemplary chassis 10 and cable clamp 12. The chassis 10 includes upper and lower module bays 14, 16 each having a 1U (one-unit) height. The expansion module 15 is disposed in the upper bay 14 and the compute module 17 is disposed in the lower bay 16. The expansion module 15 and compute module 17 each include a disk drive bay 20, and a hard disk drive 18 is disposed in each disk drive bay 20. The clamp 12 is disposed at the front of the lower module bay 16. The clamp 12 has a height that does not exceed 1U so that the clamp 12 fits within the 1U height of the lower bay 16. Also, the compute module 17 is recessed within the lower bay 16, as generally indicated at a recessed portion 21, such that the clamp 12 does not extend beyond the front edge 27 of the chassis 10. The compute module 17 includes several external electrical connectors, such as Ethernet, Serial, Infiniband, and fiber connectors 22, 23, 24, 25. Cables may be used to connect the connectors 22-25 with connectors on other devices to provide electronic communication between the connected devices. As discussed below, the cables to be connected to the connectors 22-25 may be held in the vicinity of the lower module bay 16 by the clamp 12. Additional clamps may be provided if desired. For example, the expansion module 15 may be swapped with a second compute module having several more connectors, and another clamp could be provided adjacent to the upper bay 14 for holding additional cables for connecting to the second compute module.

FIG. 3 is a front view of the clamp 12 illustrating an exemplary attachment of the clamp 12 to the chassis 10. The chassis 10 includes a pair of opposing flanges 80 and an opening 82 between the flanges 80. The clamp 12 includes a pair of opposing flanges 84 that slidably mate with the flanges 80 when the clamp 12 is inserted into the chassis 10 (into the page), to constrain the clamp 12 in the x- and y-directions. A flexible, outwardly projecting retainer tab 86 on the clamp 12 “snaps” into the opening 82 onto the chassis 10 to secure the clamp 12 in the z-direction. The clamp 12 may be subsequently removed, such as for replacement, by pressing firmly on the flexible retainer tab 86 to urge the retainer tab 86 out of the opening 82 and sliding the clamp 12 out of the chassis 10 in the z-direction (out of the page). In another embodiment, the clamp 12 may alternatively be secured to the chassis 10 using fastening hardware such as screws or bolts, or by welding or brazing the clamp 12 to the chassis 10.

FIG. 4 is a perspective view of the clamp 12 as viewed from a rearward angle. The clamp 12 includes a first clamp member (referred to in this embodiment as the “base”) 30 secured to the chassis 10 (FIG. 2) and a second clamp member (referred to in this embodiment as the “pull plate”) 33 movably secured to the base 30. The base 30 defines a first clamp surface 32 and the pull plate 33 defines an opposing second clamp surface 34 that faces the first clamp surface 32. The base 30 further includes an engagement member 42 for frictionally engaging cables. The engagement member in this embodiment comprises a deformable elastic material, conveniently formed as a strip 42, secured to the first clamp surface 32. A similar engagement member 44 is secured to the pull plate 33. The engagement member 44 is also a deformable elastic material, conveniently formed as a strip 44, secured to the second clamp surface 34. Suitable materials for the elastic strips 42, 44 include, for example, rubber, or closed-cell or open-cell foam. The pull plate 33 is movably secured to the base 30 by virtue of a shaft 38 on the pull plate 33 that rides in a shaft guide 40 on the base 30. In this embodiment, the shaft 38 has a circular cross section, and the shaft guide 40 is a through-hole on the base 30 that fits closely with the shaft 38. The shaft 38 may be formed and secured to the pull plate 33 in a variety of ways. In this embodiment, the shaft 38 includes an inner threaded fastener (“bolt”) 39 having a head 54 and is threaded into a back end of the pull plate 33. A biasing mechanism, generally indicated at 50, biases the pull plate 33 toward the base 30. The biasing mechanism 50 in this embodiment includes a spring 52 positioned on the shaft 38 between the base 30 and the head 54. The head 54 of the bolt 39 functions as a spring stop. The spring 52 engages and biases the head 54 in the direction of arrow A1 to urge the pull plate 33 toward the base 30 with sufficient force to compress the elastic strips 42, 44 around one or more cables that may be positioned between the clamp surfaces 32, 34.

The circular cross-section of the shaft 38 allows the shaft 38 to rotate within the matching circular shaft guide 40, so the pull plate 33 may be pivoted with respect to the base plate 32 about an axis of the shaft 38. However, in the position of the pull plate 33 in FIG. 4, a catch generally indicated at 55 engages the base 30 to prevent unintentional pivoting of the pull plate 33. A number of different types of catches for limiting rotation of the pull plate 33 are within the scope of the invention. In this embodiment, by way of example, the catch 55 includes a pin 56 secured to the base 30 at a position laterally spaced from the shaft 38. In the closed position of FIG. 4, the pin 56 is received into a recess or hole 57 in the pull plate 33, with the elastic strip 44 on the pull plate 33 substantially aligned with the elastic strip 42 on the base 30.

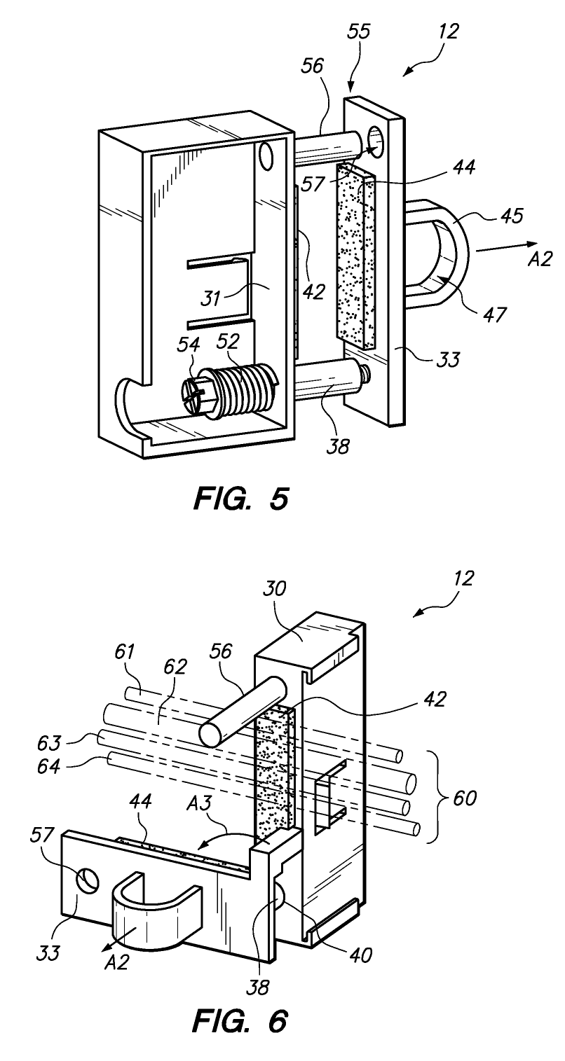

FIG. 5 is a perspective view of the clamp 12 with the pull plate 33 moved away from the base 30 by applying a force to the pull plate 33 in the direction indicated by arrow A2 against the biasing action of the spring 52. The pull plate 33 is spaced from the base to create a gap between the elastic strips 42, 44. The force in the direction A2 may be applied by hand by pulling a handle 45, which has an opening 47 sized for one or more fingers. As the pull plate 33 is moved away from the base 30, the head 54 engages and compresses the spring 52 against a rear-facing surface 31 of the base 30. The biasing action of the spring 52 is the axial reaction force provided by the spring 52 on the head 54 opposite the direction A2 in response to the compression of the spring 52. In this outward position of the pull plate 33, the catch 55 is disengaged, with the pin 56 on the base 30 removed from the hole 57 in the pull plate 33. This releases the rotational constraint previously provided by the catch 55 (see FIG. 4) and allows the pull plate 33 to now be rotated about an axis of the shaft 38.

FIG. 6 is a perspective view of the clamp 12 as viewed from the front, right side, showing the pull plate 33 pulled away from the base 30 in the direction indicated by arrow A2 and rotated in the direction indicated by arrow A3 (counterclockwise), approximately ninety degrees with respect to the base 30. In this position of the pull plate 33, the pull plate may be released to free both of a user's hands so that a bundle of cables 60 (individually indicated by reference numerals 61-64) may easily be positioned as shown over the elastic strip 42. While holding the bundles of cables 60 over the elastic strip 42, the user may rotate the pull plate 33 clockwise to re-align the elastic strip 44 on the pull plate 33 with the elastic strip 42 on the base 30, and to re-align the pin 56 with the hole 57. The user may then release the pull plate 33, such that the pull plate 33 is urged by the spring 52 (See FIG. 5) back toward the base 30, to clamp the cables 60 firmly between the pull plate 33 and the base 30 and re-insert the pin 56 into the hole 57 to lock the rotational position of the pull plate 33.

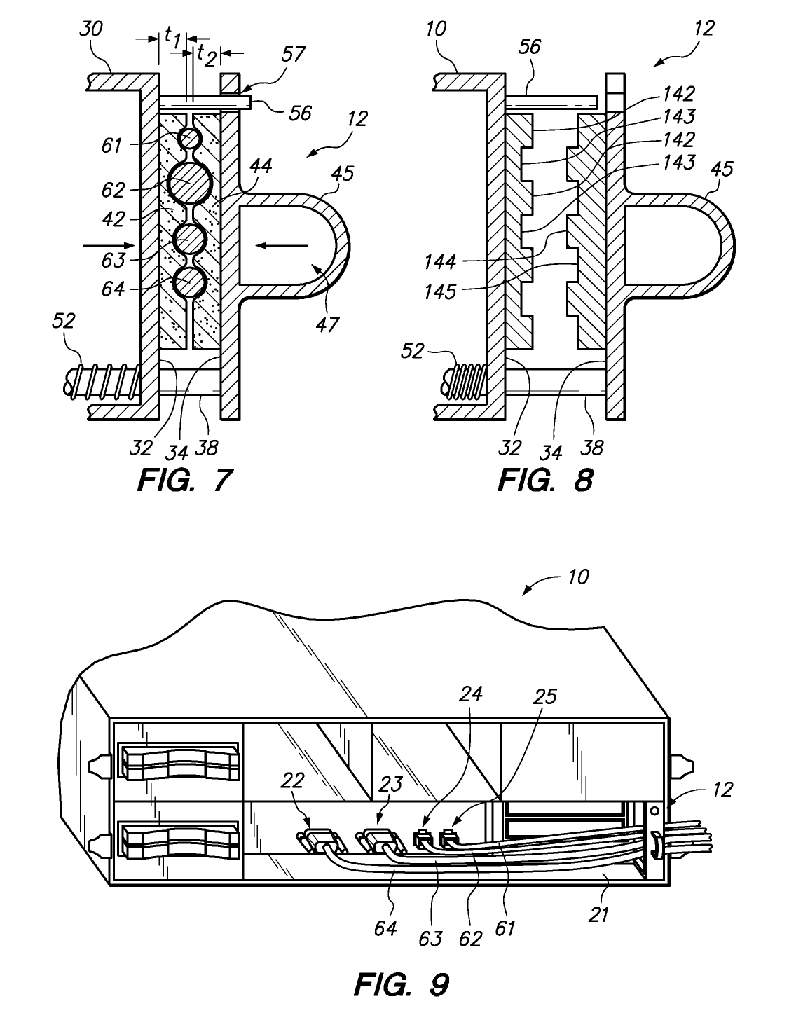

FIG. 7 is a side elevation view of the clamp 12 with the cables 61-64 clamped between the elastic strip 42 on the base 30 and elastic strip 44 on the pull plate 33 and with the pin 56 re-inserted into the hole 57 to lock the rotational position of the pull plate 33. The cables 61-64 are securely gripped between the base 30 and the pull plate 33. The optional elastic strips 42, 44 increase the grip by being compressed against and frictionally engaged with the cables 61-64. The elastic strips 42, 44 deform against the cables 61-64, gently conforming to the contours of the cables 61-64 and partially migrate into gaps there between to increase the contact area of the elastic strips 42, 44 against the cables. Parameters including the respective thicknesses t1, t2 of the elastic strips, the elasticity of material used in the elastic strips, and the biasing force provided by the spring 52 may be selected to achieve a desired amount of compression and deformation of the elastic strips 42, 44 against the cables 61-64. Although not required, the thicknesses t1, t2 of the elastic strips are typically equal. The thicknesses t1, t2 are each generally between 2 and 11 mm, and more typically 3 to 7 mm, to accommodate the range of cable diameters commonly used. Here, these parameters have been selected so that the elastic strips 42, 44 sufficiently deform to frictionally engage each of the cables 61-64, despite the different diameters of the cables.

The materials used in the elastic strips 42, 44 may also be selected to provide sufficient frictional engagement with the cables to control how securely the cables are retained by the clamp 12. A static friction coefficient of at least 0.4 is suitable for the elastic strips. Generally, increasing either of the static coefficient of friction of the elastic strips 42, 44 and/or increasing the biasing force provided by the spring 52 will increase retention of the cables. The materials 42, 44 may be treated, such as with a coating or surface treatment (e.g. texturizing) to further increase the effective coefficient of friction of the materials used in the elastic strips 42, 44. Additionally, spring parameters, such as the modulus of elasticity of the materials used to make the spring 52, the diameter of the wire used to form the spring 52, and the diameter and spacing of the coils of the spring 52, may be selected to achieve the desired spring force required to securely clamp the cables. A competing design consideration is the force required to pull the pull plate 33 against the biasing action of the spring 52. While sufficient clamping force is desired to securely clamp the cables between the plates, it is also desirable that the user may easily pull the pull plate 33, possibly using only one hand. Increasing the size of the opening 47 in the handle 45 to accommodate multiple fingers may also make it easier for the user to grasp the handle 45 and move the pull plate 33 by hand.

FIG. 8 is a side view of an alternative embodiment of the clamp 12 having an alternative engagement member comprising a plurality of ribs 142 projecting from the first clamp surface 32 and a plurality of ribs 144 projecting from the second clamp surface 34. The ribs 142 are spaced apart to form alternating recesses 143 between the ribs 142. Likewise, the ribs 144 are spaced apart to form alternating recesses 145 between the ribs 144. The ribs 142 are optionally staggered with respect to the ribs 144, such that the ribs 142 on the first clamp surface 32 align with the recesses 145 on the opposing second clamp surface 34, and the ribs 144 align with the recesses 143 on the opposing first clamp surface 32. The ribs 142, 144 are shown with a rectangular cross section, but other cross-sectional shapes may be equally suitable, such as a rounded cross-section. The ribs 142, 144 may be formed of a relatively hard plastic. The spaced-apart ribs 142, 144 provided a good gripping surface even without the use of an elastic material. However, a hybrid engagement member wherein the ribs 142, 144 are instead formed of an elastically deformable material that deforms against the clamped cables may also be suitable.

FIG. 9 is a perspective view of the chassis 10 with the cables 61-64 connected to the connectors 22-25. The cables 61-64 are routed horizontally across the front of the compute module 17 within the recessed portion 21 in front of the module 17, and are held in position by clamping the cables with the clamp 12. The cables may then be routed as desired beyond the clamp 12, such as by connecting some of the cables to a network switch (not shown) or routing them vertically to connectors on other components.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A cable clamp, comprising:
a first clamp member securable to an electronic component chassis next to an electronic module bay, the first clamp member defining a first clamp surface;
a second clamp member movably secured to the first clamp member and defining a second clamp surface facing the first clamp surface, the second clamp member being movable with respect to the first clamp member to change the spacing between the second clamp surface and the first clamp surface;
an engagement member secured to one or both of the first and second clamp surface; and
a biasing member for biasing the second clamp member toward the first clamp member to move the second clamp surface toward the first clamp surface.

2. The cable clamp of claim 1, further comprising:
a shaft on one of the first and second clamp members and a shaft guide on the other of the first and second clamp members in close engagement with the shaft, the shaft riding on the shaft guide as the second clamp member is moved with respect to the first clamp member.

3. The cable clamp of claim 2, further comprising:
a stop secured along the shaft to limit movement of the second clamp member away from the first clamp member.

4. The cable clamp of claim 3, wherein the biasing member comprises a spring positioned about the shaft between the first clamp member and the stop.

5. The cable clamp of claim 2, wherein the shaft is rotatable within the shaft guide, such that the second clamp member is rotatable with respect to the first clamp member about an axis of the shaft.

6. The cable clamp of claim 5, further comprising a catch on one of the first and second clamp members radially spaced from the shaft, the catch configured to engage the other of the first and second clamp members in response to moving the second clamp member toward the first clamp member for rotationally constraining the second clamp member with respect to the first clamp member.

7. The cable clamp of claim 1, further comprising a handle on the second clamp member configured for grasping by hand.

8. The cable clamp of claim 1, wherein the handle comprises an opening sized for receiving one or more fingers.

9. The cable clamp of claim 1, wherein the clamp has a height of approximately the height of a module bay.

10. The cable clamp of claim 1, wherein the second clamp member is movable away from the first clamp member sufficiently to create a gap of between 0.25 and 0.9 inches between the first and second clamp surfaces.

11. The cable clamp of claim 1, wherein the engagement member comprises an elastic material selected from the group consisting of rubber, closed-cell foam, and open-cell foam.

12. The cable clamp of claim 1, wherein the engagement member comprises a plurality of ribs spaced along one or both of the first and second clamp surface.

13. The cable clamp of claim 12, wherein the plurality of ribs comprises a first plurality of ribs on the first clamp surface and a second plurality of ribs on the second clamp surface, wherein the first plurality of ribs are staggered with respect to the second plurality of ribs.

14. The cable clamp of claim 11, wherein the elastic material has a static coefficient of friction of at least 0.4.

15. An apparatus, comprising:
a computer component chassis configured for removably mounting on a computer equipment rack and having at least one module bay configured for removably receiving an electronic module, the electronic module having one or more electrical connectors each configured for releasably connecting with an end of a respective one or more electronic cables; and
a clamp having a first clamp member secured to the chassis or to the rack adjacent to one of the module bays, the first clamp member defining a first clamp surface, a second clamp member defining a second clamp surface facing the first clamp surface, the second clamp member movably secured to the first clamp member and movable away from the first clamp member for receiving the one or more electronic cables between the first and second clamp surfaces, an elastic material secured to a surface of one or both of the first and second clamp surfaces, and a biasing member for biasing the second clamp member toward the first clamp member sufficient to compress and frictionally engage the elastic material with the one or more electronic cables.

16. The apparatus of claim 15, further comprising a flexible retainer tab on the first clamp member and an opening on a wall of the chassis for receiving the retainer tab and selectively securing the first clamp member to the chassis.

17. A modular computer system, comprising:
a plurality of electronic modules, each electronic module having one or more external electrical connectors;
one or more chassis, each chassis having at least one module bay configured for removably receiving one of the electronic modules;
a rack having one or more chassis bays, each chassis bay being configured to receive one of the chassis;
a plurality of cables, each cable configured for releasably connecting to the electrical connector of one of the electronic modules; and
a plurality of cable clamps, each cable clamp having a first clamp member secured to the chassis adjacent to one of the module bays and defining a first clamp surface, a second clamp member defining a second clamp surface opposing the first clamp surface, the second clamp member movably secured to the first clamp member and movable away from the first clamp member to create a gap for receiving one or more of the electronic cables between the first and second clamp surfaces, an elastic material secured to a surface of one or both of the first and second clamp surfaces, and a biasing member for biasing the second clamp member toward the first clamp member such that the elastic material is compressed against and frictionally engaged with the one or more electronic cables between the first and second clamp surfaces.

18. The modular computer system of claim 17, wherein the plurality of cables comprise a primary bundle of cables routed along the rack adjacent to the one or more chassis, the plurality of cables including subsets of cables, each subset of cables being routed to a respective module bay for connection to the electronic module disposed in the respective module bay, each subset of cables being removably clamped by the clamp adjacent to the respective module bay.

19. The modular computer system of claim 17, wherein the electronic modules are selected from the group consisting of blade servers, compute modules, hard drive modules, PCI card modules, and network switches.

20. A method, comprising:
positioning one or more chassis on a rack, each chassis having at least one module bay configured for removably receiving one of the electronic modules and a clamp having a first clamp member defining a first clamp surface and a second clamp member defining a second clamp surface;
positioning an electronic module in each module bay, each electronic module having one or more external electrical connectors;
moving the second clamp member away from the first clamp member;
positioning one or more of the electronic cables between the first and second clamp surfaces; and
biasing the second clamp member toward the first clamp member to frictionally engage the one or more electronic cables between the first and second clamp members; and
connecting the electronic cables to the electrical connectors on the electronic modules.
